(19) United States
(12) Patent Application Publication
(10) Pub. No.: US 2019/0348291 A1
(43) Pub. Date: Nov. 14, 2019

(54) METHOD FOR FORMING TRANSPARENT FLUORINE FILM, AND TRANSPARENT FLUORINE FILM FORMED THEREBY

(71) Applicant: IONES CO., LTD., Gyeonggi-do (KR)

(72) Inventors: Jae Hyuk PARK, Gyeonggi-do (KR); Dae Gean KIM, Gyeonggi-do (KR); Myoung No LEE, Gyeonggi-do (KR); Byung Ki KIM, Gyeonggi-do (KR); Hye Won SEOK, Seoul (KR)

(21) Appl. No.: 16/474,392

(22) PCT Filed: Dec. 27, 2017
(86) PCT No.: PCT/KR2017/015571

§ 371 Date: Jun. 27, 2019

(30) Foreign Application Priority Data
Dec. 27, 2016 (KR) 10-2016-0180180

(51) Int. Cl. H01L 21/3065

(52) U.S. Cl. CPC H01L 21/3065

(57) ABSTRACT

One embodiment of the present invention relates to a method for forming a transparent fluorine film, and a transparent fluorine film formed thereby, and the technical issues to be resolved are to provide a method for forming a transparent fluorine film, and transparent fluorine film formed thereby that can protect the transparent windows of display devices by having not only high transmissivity due to no or extremely small nano-structured pores in the interior, but also having high strength and adhesiveness. To that end, disclosed are a method for forming a transparent fluorine film, and a transparent fluorine film formed thereby, the method comprising the steps of: receiving transport gas from a transport gas supply unit and YF3 powder from a powder supply unit, and transporting the YF3 powder in aerosol form; and colliding and crushing the YF3 powder transported in aerosol form against a substrate in the interior of a processing chamber, and forming a transparent YF3 film on the substrate.

### TECHNICAL FIELD

An embodiment of the present invention relates to a method for forming a transparent fluorine film, and a transparent fluorine film formed thereby.

### BACKGROUND ART

Commonly known display devices include a liquid crystal display (LCD), an organic light emitting display (OLED), a field effect display (FED), an electrophoretic display device, and so on. The display typically includes a display module for displaying an image and a transparent window for protecting the display module.

In order to ensure a higher etch rate and a finer linewidth, highly corrosive chlorine or fluorine gases are used in the manufacture of semiconductor and/or display devices. Manufacturing equipment operated under such a harsh environment generally includes on its surface a protective film having high resistance against plasma and corrosive gases to attain its operational advantages and extended service life.

### PRIOR ART DOCUMENTS

### Patent Documents

1. Korean Patent Publication No. 10-2014-0126824 (Nov. 3, 2014)

2. Korean Patent Registration No. 10-1322783 (Oct. 29, 2013)

### Technical Problems to be Solved

An embodiment of the present invention provides a method for forming a transparent fluorine film having not only high transmissivity due to no or extremely small nano-structured pores in the interior but also high strength and adhesiveness, thereby protecting transparent windows of display devices, and a transparent fluorine film formed by the method.

An embodiment of the present invention also provides a method for forming a transparent fluorine film having high etching resistance against corrosive gases and high-speed colliding ion particles, thereby protecting components of semiconductor/display devices during an etching process.

### Technical Solutions

In accordance with an aspect of the present invention, there is provided a method for forming a transparent fluorine film, the method including the steps of receiving transport gas from a transport gas supply unit and YF3 powder from a powder supply unit, and transporting the YF3 powder in aerosol form, and colliding and crushing the YF3 powder transported in aerosol form against a substrate in the interior of a processing chamber, and forming a transparent YF3 film on the substrate.

The YF3 powder supplied from the powder supply unit may be pre-treated at a temperature of 1000° C. or less.

When the YF3 transparent fluorine film has a thickness in the range from 0.5 μm to 15 μm, visible light transmissivity of the YF3 transparent fluorine film may be 75% or higher.

The YF3 transparent fluorine film may be in the absence of oxygen (O).

The YF3 transparent fluorine film may have a porosity of 0.01% to 0.1%, a hardness of 8 GPa or less, and a withstand voltage of 50 V/μm or higher.

The substrate may be a transparent window of a display device or a component exposed to a plasma environment. The transparent window may be a glass substrate, a plastic substrate, a sapphire substrate or a quartz substrate, and the component is an internal component of a processing chamber for manufacturing semiconductor or display devices. The component may be one selected from the group consisting of an electro static chuck, a heater, a chamber liner, a shower head, a boat for CVD (Chemical Vapor Deposition), a focus ring, a wall liner, a shield, a cold pad, a source head, an outer liner, a deposition shield, an upper liner, an exhaust plate, an edge ring and a mask frame.

In accordance with another aspect of the present invention, there is provided a transparent fluorine film formed by the method, wherein when the YF3 transparent fluorine film has a thickness in the range from 0.5 μm to 15 μm, visible light transmissivity of the YF3 transparent fluorine film may be 75% or greater.

### Advantageous Effects

As described above, the present invention provides a method for forming a transparent fluorine film and a transparent fluorine film formed thereby. Since the transparent fluorine film has high transmissivity due to no or extremely small porosity (or extremely high packing factor) and nano-structured pores and a high hardness (strength) and adhesiveness, transparent windows of display devices can be protected. The transparent fluorine film according to the present invention has a porosity of about 0.01% to about 0.1%, transmissivity of about 75% or higher (based on 0.5 μm to 15 μm in film thickness) and a hardness of about 8 GPa, so that it can be adequately used as a protective film for a transparent window.

In addition, the present invention provides a method for forming a transparent fluorine film and a transparent fluorine film formed thereby, the transparent fluorine film having high etching resistance against corrosive gases and high-speed colliding ion particles due to a high hardness and capable of protecting components of semiconductor/display devices during an etching process. Since the transparent fluorine film according to the present invention has a high hardness under a high-density plasma etching environment, it can be adequately used as a protective film of a component exposed to a plasma etching processing condition, like a semiconductor/display component. In addition, the transparent fluorine film according to the present invention has a withstand voltage of about 50 V/μm to about 150 V/μm, which is a sufficiently satisfactory range in the manufacture of the semiconductor/display component.

### BRIEF DESCRIPTION OF DRAWINGS

FIG. 1 is a schematic diagram of an apparatus for forming a transparent fluorine film according to an embodiment of the present invention.

FIG. 2 is a flow diagram illustrating a method for forming a transparent fluorine film according to an embodiment of the present invention.

FIGS. 3A, 3B and 3C are a plan view, a cross-sectional view and a plane photo of a transparent fluorine film according to an embodiment of the present invention, respectively.

FIG. 4 is a graph showing X-ray diffraction patterns indicating phase analysis results after pre-treatment of YF3 powder according to an embodiment of the present invention.

FIGS. 5A and 5B are graphs showing transmissivity of a YF3 transparent fluorine film using YF3 powder pre-treated according to an embodiment of the present invention depending on wavelengths and thicknesses, respectively.

FIG. 6 is a graph showing energy-dispersive X-ray spectroscopy (EDS) analysis results of a YF3 transparent fluorine film according to an embodiment of the present invention.

FIGS. 7A and 7B show microscopic images showing YF3 powder used for a YF3 transparent fluorine film according to an embodiment of the present invention.

FIG. 8 is a graph showing physical properties of YF3 powder for forming a transparent fluorine film according to an embodiment of the present invention.

FIG. 9 is a graph showing hardness data of a transparent fluorine film according to an embodiment of the present invention.

### BEST MODE FOR CARRYING OUT THE INVENTION

Hereinafter, a preferred embodiment of the present invention will be described in detail.

Various embodiments of the present invention may be embodied in many different forms and should not be construed as being limited to the example embodiments set forth herein. Rather, these example embodiments of the disclosure are provided so that this disclosure will be thorough and complete and will convey inventive concepts of the disclosure to those skilled in the art.

The terminology used herein is for the purpose of describing particular embodiments only and is not intended to be limiting of the disclosure. As used herein, the singular forms are intended to include the plural forms as well, unless the context clearly indicates otherwise. It will be further understood that the terms “comprise” and/or “comprising,” when used in this specification, specify the presence of stated features, numbers, steps, operations, elements, and/or components, but do not preclude the presence or addition of one or more other features, numbers, steps, operations, elements, components, and/or groups thereof. In addition, as used herein, the term “and/or” includes any and all combinations of one or more of the associated listed items.

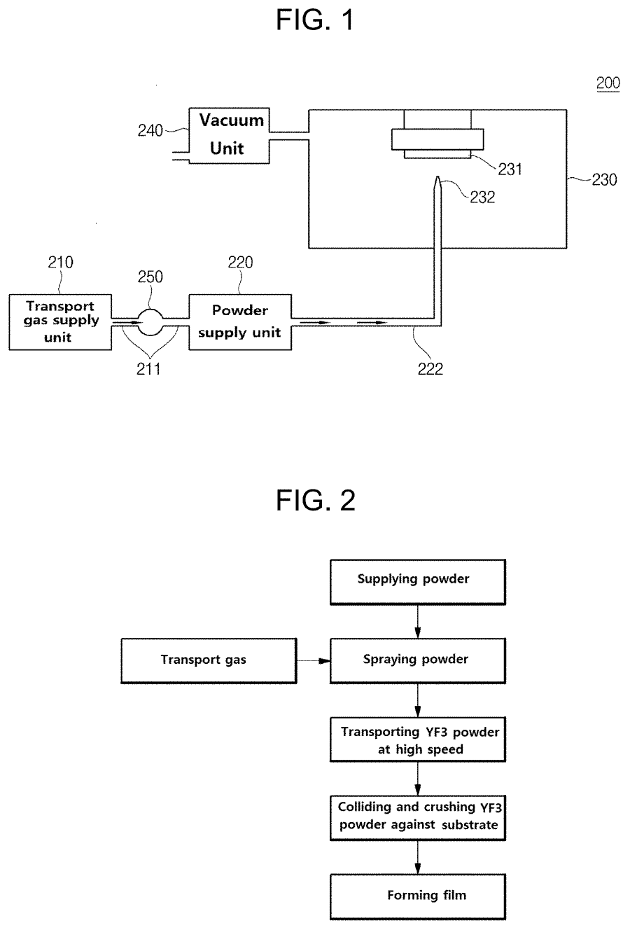

FIG. 1 is a schematic diagram of an apparatus for forming a transparent fluorine film according to an embodiment of the present invention, and FIG. 2 is a flow diagram illustrating a method for forming a transparent fluorine film according to an embodiment of the present invention.

As shown in FIG. 1, the YF3 transparent fluorine film forming apparatus 200 according to the present invention includes a transport gas supply unit 210, a powder supply unit 220 storing and supplying YF3 powder, a transport pipe 222 for transporting the YF3 powder in aerosol form at a high speed using a transport gas received from the powder supply unit 220, a nozzle 232 for coating/stacking or spraying the YF3 powder from the transport pipe 222 on a substrate 231, and a processing chamber 230 for colliding and crushing the YF3 powder from the nozzle 232 against a surface of the substrate 231 and forming the YF3 transparent fluorine film having a predetermined thickness. Here, the aerosol form means that the YF3 powder having a diameter in the range from about 0.1 μm to about 10 μm is dispersed in the transport gas.

The method for forming the transparent fluorine film according to an embodiment of the present invention will now be described with reference to FIGS. 1 and 2.

The transport gas stored in the transport gas supply unit 210 may include, but not limited to, one or two kinds of mixtures selected from the group consisting of oxygen, helium, nitrogen, argon, carbon dioxide, hydrogen, and equivalents thereof. The transport gas is directly supplied from the transport gas supply unit 210 to the powder supply unit 220 through a pipe 211, and the flow rate and pressure of the transport gas may be controlled by a flow rate controller 250.

The powder supply unit 220 stores and supplies a large quantity of YF3 powder. The YF3 powder is in an aerosol form due to the transport gas of the transport gas supply unit 210 and is supplied to the substrate 231 provided in the processing chamber 230 through the transport pipe 222 and the nozzle 232.

The processing chamber 230 may be maintained in a vacuum while forming the YF3 transparent fluorine film. To this end, a vacuum unit 240 may be connected to the processing chamber 230. In more detail, the pressure of the processing chamber 230 may be in the range from about 1 Pascal to about 800 Pascals, and the pressure of the YF3 powder transported by the high-speed transport pipe 222 may be in the range from about 500 Pascals to about 2000 Pascals. However, under all circumstances, the pressure of the high-speed transport pipe 222 should be higher than that of the processing chamber 230.

In addition, the internal temperature of the processing chamber 230 may be maintained to be in the range from about 0° C. to about 30° C. Therefore, a separate element for increasing or decreasing the internal temperature of the processing chamber 230 may not need to be provided. That is to say, the internal temperature of the processing chamber 230 may be maintained at a temperature in the range from about 0° C. to about 30° C. without separately heating a transport gas and/or a substrate. Therefore, according to the present invention, the substrate may not be susceptible to thermal shock when a transparent protective film is formed for a window of a display device.

However, in some cases, in order to improve deposition efficiency and compactness of a YF3 transparent fluorine film, a transport gas or/and a substrate may be heated at a temperature of about 30° C. to about 1000° C. That is to say, the transport gas in the transport gas supply unit 210 or the substrate 231 in the processing chamber 230 may be heated by a separate heater (not shown). The stress applied to YF3 powder while forming the YF3 transparent fluorine film may be reduced by heating the transport gas or/and the substrate, thereby obtaining the YF3 transparent fluorine film having small and compact pores. Here, if the temperatures of the transport gas or/and the substrate are higher than about 1000° C., the YF3 powder may be melted to cause a rapid phase transition. Accordingly, the YF3 transparent fluorine film may have an increased porosity (a reduced packing factor), making the internal structure of the YF3 transparent fluorine film unstable.

However, the present invention does not limit the temperature ranges to those disclosed herein. The ranges of the transport gas, the substrate and/or the internal temperature of the processing chamber may be adjusted to be between 0° C. and 1000° C. according to characteristics of the substrate on which the film is to be formed. That is to say, as described above, in order to form a film on a window of a display device, a processing temperature in the range from about 0° C. to about 30° C. may be supplied, and in order to form a film on semiconductor/display manufacturing equipment, a processing temperature in the range from about 0° C. to about 1000° C. may be supplied.

Meanwhile, as described above, a pressure difference between the processing chamber 230 and the high-speed transport pipe 222 (or the transport gas supply unit 210 or the powder supply unit 220) may be about 1.5 to 2000 times. If the pressure difference is smaller than about 1.5 times, it may be difficult to transport the YF3 powder at a high speed. If the pressure difference is greater than about 2000 times, the substrate surface may be over-etched by the YF3 powder.

The YF3 powder supplied from powder supply unit 220 is rapidly transported to the processing chamber 230 according to the pressure difference between the processing chamber 230 and the transport pipe 222 while being sprayed through the transport pipe 222.

In addition, the nozzle 232 connected to the transport pipe 222 is provided in the processing chamber 230 to make the YF3 powder collide against the substrate 231 at a speed of about 100 m/s to about 500 m/s. That is to say, the YF3 powder supplied through the nozzle 232 is crushed and/or milled by kinetic energy obtained during transporting and collision energy generated during high-speed collision, thereby ultimately forming the YF3 transparent fluorine film having a predetermined thickness on the surface of the substrate 231.

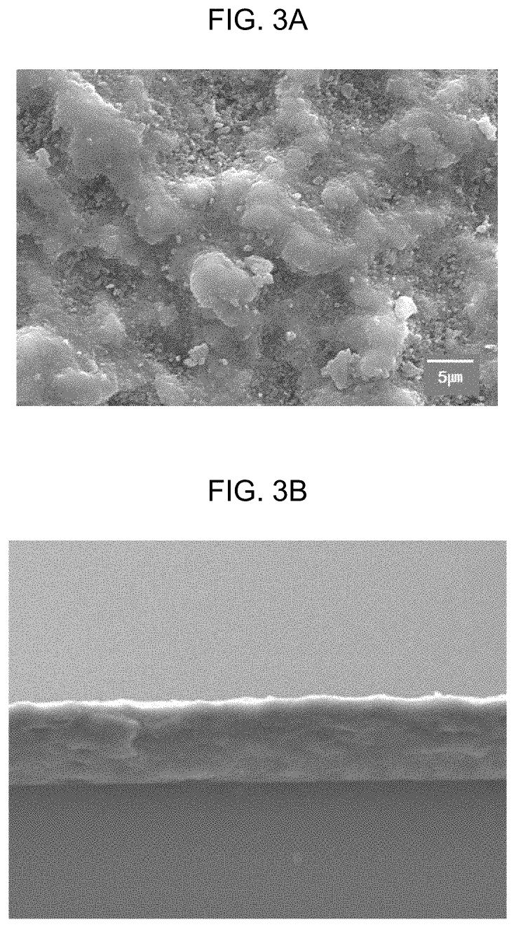

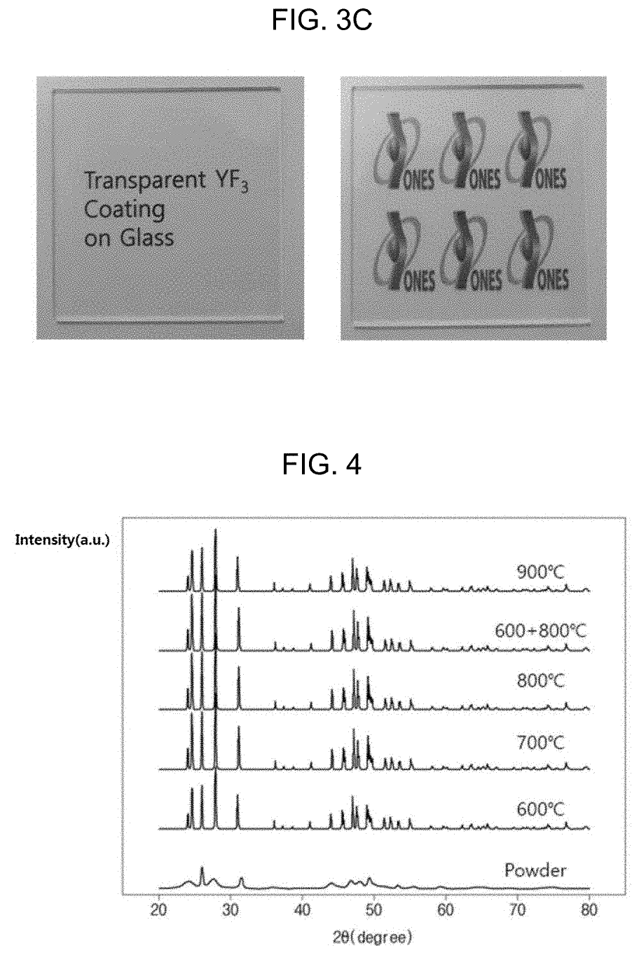

FIGS. 3A, 3B and 3C are a plan view, a cross-sectional view and a plane photo of a transparent fluorine film according to an embodiment of the present invention, respectively.

As shown in FIGS. 3A and 3B, the YF3 transparent fluorine film had no microcracks observed from its surface and demonstrated a porosity of 0.01% to 0.1%. In addition, as shown in FIG. 3C, the YF3 transparent fluorine film had high transmissivity, suggesting that the YF3 transparent fluorine film can be adequately used as a protective film for a transparent window.

Here, the porosity of the YF3 transparent fluorine film was calculated by obtaining an image of the cut YF3 transparent fluorine film photographed using a scanning electron microscope (SEM) and processing the SEM image using image processing software. In addition, as described above, since the porosity of the YF3 transparent fluorine film is between 0.01% and 0.1%, the YF3 transparent fluorine film may have a packing factor between 99.90% and 99.99%. The transnmissivity of the YF3 transparent fluorine film will be further described below.

FIG. 4 is a graph showing X-ray diffraction patterns indicating phase analysis results after pre-treatment of YF3 powder according to an embodiment of the present invention. Here, the X-axis indicates 2θ (degree) and the Y-axis indicates intensity (a.u.).

As shown in FIG. 4, the YF3 powder has increasing X-ray diffraction intensities after being pre-treated (heat-treated) at 600° C., 700° C., 800° C., 600° C.+800° C., and 900° C., respectively, compared to the YF3 powder without pre-treatment. That is to say, the intensities of the YF3 powder gradually increase bit by bit with heat-treatment temperatures rising. However, the X-ray diffraction angles 2θ are substantially the same before and after pre-treatment (heat treatment).

Thus, the YF3 powder demonstrated little change in physical properties before and after pre-treatment (heat treatment) at about 900° C. or below, and it was possible to obtain such transmissivity as desired in the present invention when the YF3 transparent fluorine film was formed under the aforementioned processing conditions using the YF3 powder.

Meanwhile, the heat treatment may be performed in an oxygen or air atmosphere. The heat treatment may also be performed in a nitrogen or argon atmosphere. In the present invention, the pre-treatment was performed in the presence of air under temperature-rising conditions of temperatures rising from 300° C. to 900° C., a temperature rising rate being 5° C./min and a heating time being about 2 hours, and natural cooling was performed using heat treatment equipment.

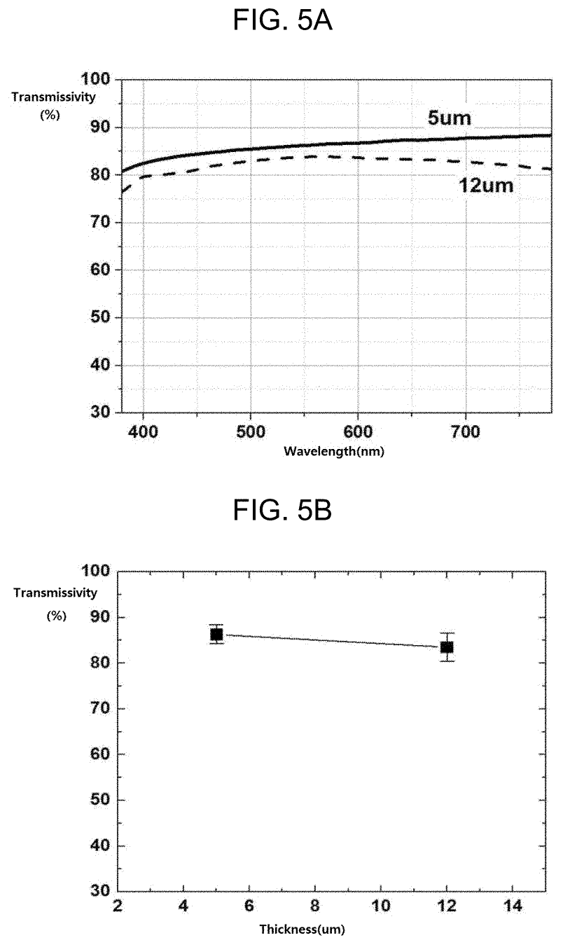

FIGS. 5A and 5B are graphs showing transmissivity of a YF3 transparent fluorine film using YF3 powder pre-treated according to an embodiment of the present invention depending on wavelengths and thicknesses, respectively.

In FIG. 5A, the X-axis indicates wavelengths (nm) and the Y-axis indicates transmissivity (%). In FIG. 5B, the X-axis indicates film thickness (μm) and the Y-axis indicates transmissivity (%).

If the YF3 transparent fluorine film has a thickness in the range from about 0.5 μm to about 15 μm, the transmissivity of the YF3 transparent fluorine film observed for visible light (380 nm to 780 nm) was about 75% or higher.

In an example, as shown in FIGS. 5A and 5B, when the YF3 transparent fluorine film formed using the YF3 powder pre-treated in the above-described manner had a thickness of about 5 μm, the visible light (380 nm to 780 nm), and when the YF3 transparent fluorine film had a thickness of about 12 μm, the transmissivity of the YF3 transparent fluorine film was about 75%˜85%. Therefore, it is confirmed that the YF3 transparent fluorine film according to the present invention can be adequately used as a protective film for a transparent window of a display device.

However, since the YF3 transparent fluorine film itself was not formed when an attempt was made to form the YF3 transparent fluorine film using the YF3 powder without pre-treatment (base material), transmissivity data for both cases could not be compared. That is to say, it was not possible to form a film having a predetermined thickness on a substrate using YF3 powder on which heat treatment was not performed, thereby making transmissivity comparison impossible.

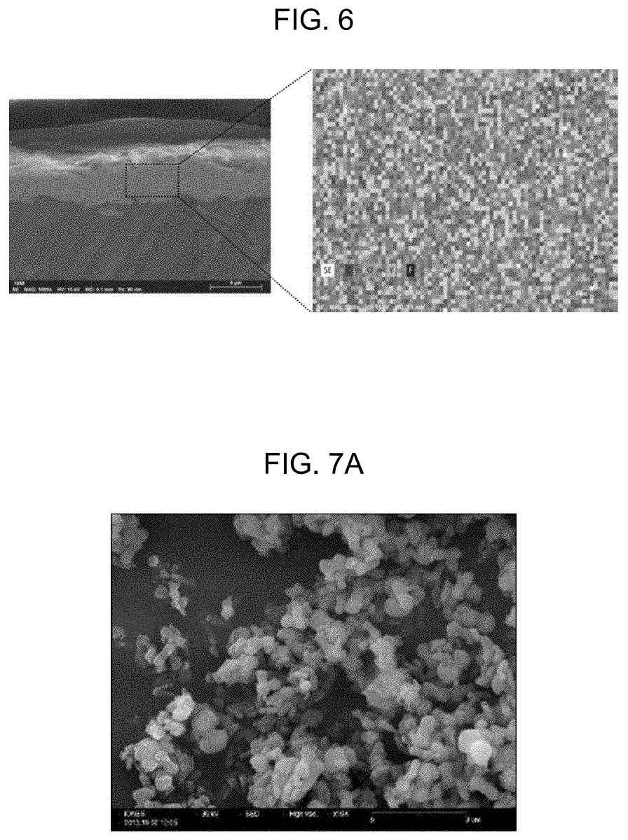

FIG. 6 is a graph showing energy-dispersive X-ray spectroscopy (EDS) analysis results of a YF3 transparent fluorine film according to an embodiment of the present invention.

As shown in FIG. 6, only fluorine (F) and yttrium (Y) were detected from the YF3 transparent fluorine film formed by the method according to the present invention, and oxygen (O) was not detected. As described above, since oxygen (O) was not detected in the YF3 transparent fluorine film, the YF3 transparent fluorine film according to the present invention demonstrated improved transmissivity, strength and adhesiveness while having a reduced porosity.

Here, after the YF3 transparent fluorine film was formed using YF3 powder, oxy-fluoride treatment may be performed in an oxygen or air atmosphere to further increase the film intensity. In this case, it was confirmed that a very small amount of oxygen was diffused into the film in a weight ratio of 4:39, as analyzed by EDS. The oxy-fluoride treatment yielded an yttrium oxide fluoride (Y₆O₅F₈) film, rather than the YF3 film, confirming that a mechanical property of the film was improved. However, it may be difficult to apply the oxy-fluoride treatment to an optically transparent substrate (e.g., a glass substrate, a quartz substrate, or a plastic substrate) due to a high-temperature process (500° C. to 1000° C.). Specifically, the transmissivity of the film was noticeably lowered due to the oxygen (O) contained therein.

Table 1 shows comparison results of various physical properties of the YF3 transparent fluorine films using YF3 powder with and YF3 powder without pre-treatment.

TABLE 1

| | With pre-treatment (O) | Without pre-treatment (X) |
|---|---|---|
| Hardness | 5 GPa~8 GPa | Film not formed |
| Porosity | 0.01~1.0% | |
| Withstand voltage | 50~150 V/μm | |

As indicated in Table 1, in case of using pre-treated YF3 powder, the obtained YF3 transparent fluorine film had a hardness of 8 GPa or less, a porosity of 0.01% to 0.1%, and a withstand voltage of 50 V/μm or higher. However, in case of using YF3 powder without pre-treatment, any film was not formed at all, so that hardness, porosity and withstand voltage data were not acquired.

As described above, since the YF3 transparent fluorine film according to the present invention has good properties in view of hardness, porosity and withstand voltage, it can be used as a protective film of a transparent window of a display device or a component of semiconductor/display devices exposed to a plasma environment.

The hardness of the YF3 transparent fluorine film may be measured from a mark created by pressing the film using a diamond quadrangular pyramid tool. The porosity of the YF3 transparent fluorine film may be calculated by cutting the film, obtaining an image of the cut film photographed using a scanning electron microscope (SEM) and analyzing the SEM image using a computer having image processing software installed therein. The withstand voltage of the YF3 transparent fluorine film may be measured by installing two electrodes on the YF3 transparent fluorine film. These measuring methods are well known to one skilled in the art, and detailed descriptions thereof will be omitted.

Meanwhile, the substrate on which the YF3 transparent fluorine film according to the present invention is located may be a transparent window of a display device or a component exposed to a plasma environment, as described above. Specifically, the transparent window may be a glass substrate, a plastic substrate, a sapphire substrate or a quartz substrate, and the component may be an internal component of a processing chamber for manufacturing semiconductor or display devices. Particularly, according to the present invention, when the transparent window is a glass substrate or a plastic substrate, since the YF3 transparent protective film is provided at a low temperature in the range from about 0° C. to about 30° C., the glass substrate or the plastic substrate can be prevented from being damaged.

Here, the plastic substrate may include a thermoplastic semicrystalline polymer having a glass transition temperature (Tg) of about 140° C. and a melting temperature (Tm) of about 340° C., such as, for example, polyethylene terephthalate (PET), polyethylene naphthalate (PEN), or polyether ether ketone (PEEK). In addition, the plastic substrate may include a thermoplastic amorphous plastic substrate, such as, for example, polycarbonate (PC) having a Tg of about 150° C., which is higher than the semicrystalline plastic, and exhibiting no melting temperature, or polyethersulfone (PES) having a Tg of about 220° C. In addition, the plastic substrate may be prepared from a material having a relatively high heat resistance, such as, for example, polyimide (PI) or polyarylate (PAR).

In addition, the component exposed to the plasma environment may include one selected from the group consisting of an electro static chuck, a heater, a chamber liner, a shower head, a boat for chemical vapor deposition (CVD), a focus ring, a wall liner, a shield, a cold pad, a source head, an outer liner, a deposition shield, an upper liner, an exhaust plate, an edge ring, a mask frame and equivalents thereof, but the present invention does not limit the substrate or the component having the film formed thereon to those disclosed herein.

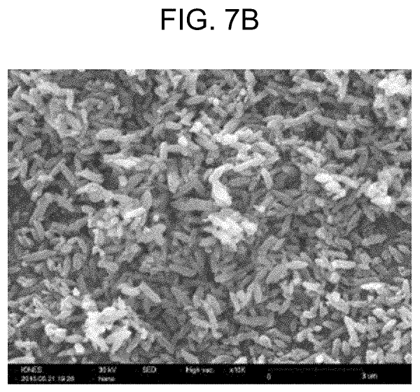

FIGS. 7A and 7B show microscopic images showing YF3 powder used for a YF3 transparent fluorine film according to an embodiment of the present invention.

As shown in FIGS. 7A and 7B, the YF3 powder may have an average particle diameter in the range from about 0.1 μm to about 10 μm, preferably in the range from about 0.1 μm to about 3 μm. In addition, the YF3 powder may have a substantially needle-like shape or a spherical shape, but aspects of the present invention are not limited thereto.

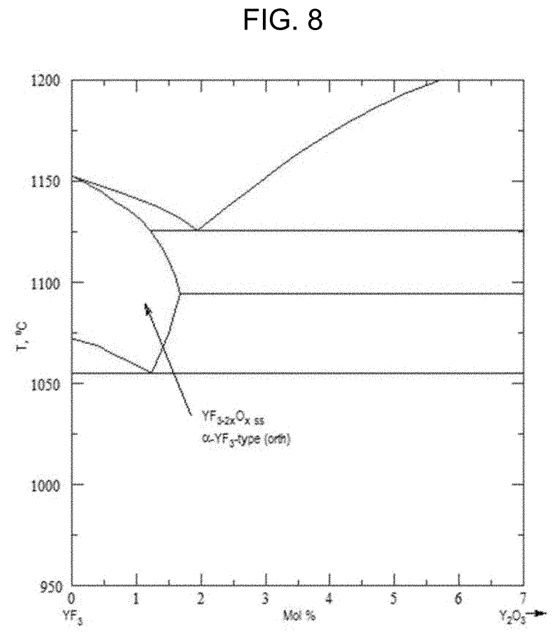

FIG. 8 is a graph showing physical properties of YF3 powder for forming a transparent fluorine film according to an embodiment of the present invention. In FIG. 8, the X-axis indicates YF3 proportions (i.e., 0: YF3 100 Mol % and Y2O3 0 Mol %; and 7: YF3 93 Mol % and Y2O3 7 Mol %), and the Y-axis indicates atmospheric temperatures (° C). Notably, in a case of YF3 100 Mol %, as shown, the YF3 powder exists in a single phase up to the atmospheric temperature of 1050° C. That is to say, until the atmospheric temperature 1050° C. is reached, the YF3 powder does not undergo decomposition, phase change or mixing with oxygen. Therefore, according to the present invention, the YF3 powder may be pre-treated (heat-treated) up to about 1050° C. When the YF3 powder is heat-treated at a temperature ranging from about 1050° C. to about 1150° C., oxygen (O) may be diffused to be contained in the YF3 powder, causing a phase change.

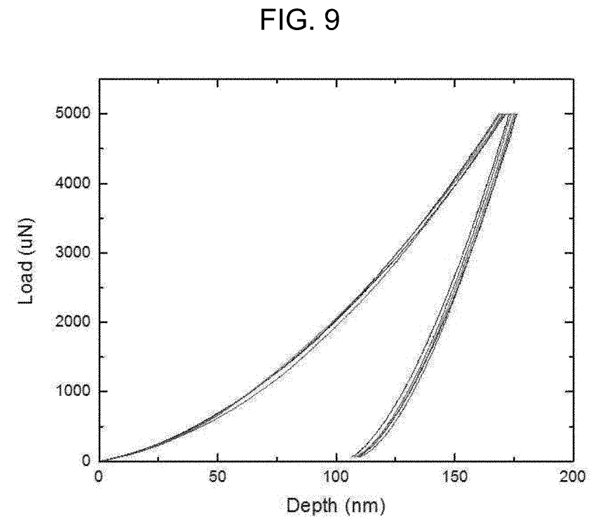

FIG. 9 is a graph showing hardness data of a transparent fluorine film according to an embodiment of the present invention.

In FIG. 9, the X-axis indicates depths (nm) of the YF3 transparent film pressed by a diamond quadrangular pyramid tool, and the Y-axis indicates a load (μN) applied by the diamond quadrangular pyramid tool. As shown in FIG. 9, when the diamond quadrangular pyramid tool pressed the YF3 transparent film with a load of about 0 to 5000 μN, a recessed mark having a depth of about 0 to 175 nm was produced in the YF3 transparent film. When the diamond quadrangular pyramid tool was taken away from the YF3 transparent film with a load of about 5000 to 0 μN, the recessed mark in the YF3 transparent film had a depth of about 175 to 110 nm.

The hardness of the YF3 transparent fluorine film can be calculated based on the graph data. In such a way, the hardness of about 7.5 GPa can be obtained. Therefore, it is confirmed that the YF3 transparent fluorine film of the present invention has a hardness of about 8 GPa or less.

Here, even after the diamond quadrangular pyramid tool was taken away from the YF3 transparent film, the recessed mark having a depth of about 110 nm remained in YF3 transparent film, suggesting that thermoplastic deformation occurred to the YF3 transparent film.

Although the foregoing embodiments have been described to practice the method for forming a transparent fluorine film of the present invention and the transparent fluorine film formed thereby, these embodiments are set forth for illustrative purposes and do not serve to limit the invention. Those skilled in the art will readily appreciate that many modifications and variations can be made, without departing from the spirit and scope of the invention as defined in the appended claims, and such modifications and variations are encompassed within the scope and spirit of the present invention.

1. A method for forming a transparent fluorine film, the method comprising the steps of:
receiving transport gas from a transport gas supply unit and YF3 powder from a powder supply unit, and transporting the YF3 powder in aerosol form; and
colliding and crushing the YF3 powder transported in aerosol form against a substrate in the interior of a processing chamber, and forming a transparent YF3 film on the substrate.

2. The method of claim 1, wherein the YF3 powder supplied from the powder supply unit is pre-treated at a temperature of 1000° C. or less.

3. The method of claim 1, wherein the visible light transmissivity of the YF3 transparent fluorine film is 75% or higher when the YF3 transparent fluorine film has a thickness in the range from 0.5 μm to 15 μm.

4. The method of claim 1, wherein oxygen (O) is not detected in the YF3 transparent fluorine film.

5. The method of claim 1, wherein the YF3 transparent fluorine film has a porosity of 0.01% to 0.1%, a hardness of 8 GPa or less, and a withstand voltage of 50 V/μm or higher.

6. The method of claim 1, wherein the substrate is a transparent window of a display device or a component exposed to a plasma environment.

7. The method of claim 6, wherein the transparent window is a glass substrate, a plastic substrate, a sapphire substrate or a quartz substrate, and the component is an internal component of a processing chamber for manufacturing semiconductor or display devices.

8. The method of claim 7, wherein the component is selected from the group consisting of an electro static chuck, a heater, a chamber liner, a shower head, a boat for CVD (Chemical Vapor Deposition), a focus ring, a wall liner, a shield, a cold pad, a source head, an outer liner, a deposition shield, an upper liner, an exhaust plate, an edge ring and a mask frame.

9. A transparent fluorine film formed by the method claimed in claim 1, wherein the visible light transmissivity of the YF3 transparent fluorine film is 75% or greater when the YF3 transparent fluorine film has a thickness in the range from 0.5 μm to 15 μm.

10. The transparent fluorine film of claim 9, wherein oxygen (O) is not detected in the YF3 transparent fluorine film.

11. The transparent fluorine film of claim 9, wherein the YF3 transparent fluorine film has a porosity of 0.01% to 0.1%, a hardness of 8 GPa or less, and a withstand voltage of 50 V/μm or higher.
